(19) United States
(12) Patent Application Publication
(10) Pub. No.: US 2024/0118533 A1
(43) Pub. Date: Apr. 11, 2024

(54) OPTO-MECHANICAL STRUCTURE AND ASSOCIATED MANUFACTURING METHODS

(71) Applicant: COMMISSARIAT À L’ENERGIE ATOMIQUE ET AUX ENERGIES ALTERNATIVES, PARIS (FR)

(72) Inventors: Thomas FURCATTE, GRENOBLE CEDEX 09 (FR); Marc SANSA PERNA, GRENOBLE CEDEX 09 (FR); Sébastien HENTZ, GRENOBLE CEDEX 09 (FR); Munique KAZAR MENDES, GRENOBLE CEDEX 09 (FR)

(21) Appl. No.: 18/481,751

(22) Filed: Oct. 5, 2023

(30) Foreign Application Priority Data
Oct. 6, 2022 (FR) 2210229

(51) Int. Cl. G02B 26/00; B81B 3/00; H10N 30/20

(52) U.S. Cl. CPC G02B 26/001; B81B 3/0021; H10N 30/2042; B81B 2201/042

(57) ABSTRACT

An opto-mechanical structure includes a substrate extending along a plane; a support element arranged on the substrate; a conductive element adapted to create an electric field oriented perpendicularly to the plane of the substrate; and an opto-mechanical resonator. The opto-mechanical resonator includes a mechanically movable element made of a piezoelectric material and arranged on the support element, the piezoelectric material being chosen so that the electric field created by the conductive element when the same is subjected to an electric potential causes a displacement of the movable element; an optical resonator coupled to the movable element. The conductive element is located above or below the movable element, at a non-zero distance from the movable element, the conductive element and the movable element having a surface facing each other.

### CROSS-REFERENCE TO RELATED APPLICATIONS

This application claims priority to French Patent Application No. 2210229, filed Oct. 6, 2022, the entire content of which is incorporated herein by reference in its entirety.

### FIELD

The technical field of the invention is that of MOEMS (micro electro-opto-mechanical systems).

The present invention relates to an opto-mechanical structure as well as a first manufacturing method and a second manufacturing method enabling such a structure to be obtained.

### BACKGROUND

MOEMSs generally comprise a mechanical resonator interacting with light signals, typically coherent laser light. Thus, the laser light makes it possible to actuate or even detect movement of the mechanical resonator. However, it is also possible to actuate the mechanical resonator of a MOEMS by piezoelectric effect (referred to as piezoelectric actuation), that is a structure comprising a mechanical resonator with an optical readout and a piezoelectric actuator. Such systems have a wide range of applications, from resonant sensors to time bases and frequency converters. In such systems, piezoelectric actuation is related to the inverse piezoelectric effect, which involves mechanical deformation of a material when it is subjected to an electric field. This is a standard actuation technique in microsystems, whether for resonant or static mechanical structures.

Piezoelectric actuation requires the ability to generate an electric field, which can be generated, for example, by applying a potential between two electrodes or by moving electric charge carriers (this is the case, for example, with microwave resonators of the inductance-capacitance (LC) or resistance-capacitance (RC) circuit type, which can serve as actuation structures).

However, when the element to be actuated is an opto-mechanical resonator, then the actuation should follow a strict set of rules. Firstly, by definition, a mechanical resonator should be placed in a cavity that allows it to move freely. This cavity can thus be empty, filled with a gas or a liquid. The actuating structure should therefore be positioned in such a way as to interfere as little as possible with the resonator mechanical displacement field. Secondly, the mechanical resonator can also act as an optical cavity, so that an electromagnetic wave propagates therewithin. This wave includes an evanescent component located outside the cavity, having an exponential spatial decrease. If this evanescent portion is coupled with a metal, it becomes absorbed. In this context, it is therefore not possible to place actuating electrodes on the opto-mechanical resonator or in its immediate vicinity. Thirdly, in order to generate strong electric fields in a reproducible way, it is necessary to control distance between the actuating electrodes and the opto-mechanical resonator. It is therefore important to have an actuation means that is compatible with electronic micro-fabrication methods, so that everything can be directly integrated onto the same chip. In the state of the art, there are several actuator types depending on the structure of the opto-mechanical resonator.

In some structures of the state of the art, opto-mechanical systems can be structurally dissociated: the optical cavity and the mechanical resonator are produced using two separate elements. Mechanical actuation can thus take place by direct contact between actuating electrodes and the mechanical resonator. Two standard geometries are to sandwich the piezoelectric material between two electrodes of different electrical polarisation, in order to excite a Film Bulk Acoustic Resonator (FBAR), or to deposit interdigitated electrodes onto the surface of the mechanical resonator in order to generate coupling with Surface Acoustic Waves (SAW). However, in this case, electrodes tend to disturb movements of the mechanical resonator and therefore its resonance properties.

In other structures of the state of the art, actuation via an element from a second chip is implemented. This is typically the case where actuation is not preformed via electrodes but via a microwave resonator. The latter, generally designed using a superconducting material, have electromagnetic resonance modes. These modes comprise a confined and guided microwave wave propagating within the structure, as well as an evanescent component around the structure. Despite an exponential spatial decrease, the low frequency of micrometric waves allows the presence of an electric field with a sufficient intensity to be able to actuate a mechanical structure several tens of micrometres from the superconducting resonator. At this distance, the evanescent component of the optical wave (of much higher frequency) is completely extinguished, thus not inducing any additional losses. However, in the state of the art, these superconducting resonators are designed on different chips, simplifying the manufacturing method but making alignment more difficult and measurement reproducibility more uncertain.

Furthermore, in addition to the difficulties already described, it is appropriate to take account of one of the features of piezoelectric actuation: the vectorial orientation of coupling. Indeed, under the effect of an electric field, each material will undergo normal stress or shear stress in some direction in space, which in turn depends on the orientation of the electric field. To achieve effective actuation, it is therefore necessary to align the electric field along a defined axis taking the desired deformation into account. The piezoelectric tensor of a material provides the link between these two quantities. It is linked to the crystallographic structure of the material in question.

In directly integrated actuator structures of the state of the art, electric fields have a main component that is horizontal relative to the substrate surface. For example, Fong et al. in “Microwave-assisted coherent and nonlinear control in cavity piezo-optomechanical systems” arrange electrodes in the same plane as the optomechanical resonator. An alternative developed by Zou et al. in “Cavity piezomechanical strong coupling and frequency conversion on an aluminum nitride chip” consists in lowering one of the two electrodes to the level of the substrate. The electric field becomes transverse, so the mechanical resonator is subjected to both the vertical and horizontal components of the electric field. A fraction of the electric field intensity is then not coupled with the material, making this geometry inefficient. In a somewhat different structure (since no mechanical resonator is present, the authors performing electro-optical modulation), Wang et al. in “On-Chip Optical Microresonators With High Electro-Optic Tuning Efficiency” suggest depositing a metal layer onto the portions of the optical resonator through which the optical wave (in this case, only the edges of the disc are sensitive) does not pass. At the cost of considerable technological complexity to achieve electrical contact, this alternative is very specific to the case of discs which confine the wave to located portions of the resonator. In addition, since the metal is in direct contact with the optical cavity, if the latter is also a mechanical resonator, additional losses are to be expected.

Thus, none of the structures of the state of the art can meet the requirements for actuating an opto-mechanical resonator.

### SUMMARY

An aspect of the invention offers a solution to the problems discussed above, by providing a structure that can meet requirements for piezoelectric actuation of an opto-mechanical resonator.

For this, a first aspect of the invention relates to an opto-mechanical structure including:
a substrate extending along a plane;
a support element arranged on the substrate;
at least one conductive element adapted to create an electric field oriented perpendicularly to the plane of the substrate;
an opto-mechanical resonator including:
a mechanically movable element made of a piezoelectric material and arranged on the support element, the piezoelectric material being chosen so that the electric field created by the conductive element when the same is subjected to an electric potential causes a displacement of the movable element;
an optical resonator coupled to the movable element;
the at least one conductive element being located above and/or below the movable element, at a non-zero distance from the movable element, the conductive element and the movable element having at least one surface facing each other.

By virtue of an aspect of the invention, the conductive element or elements in charge of actuation are not in direct contact with the movable element (and therefore the mechanical resonator). They therefore allow free movement thereof and eliminate the risk of absorption of evanescent waves when such waves are used for reading. Furthermore, the actuating means is (are) located above and/or below the movable element, which makes it possible to generate an actuation electric field perpendicular to the movable element and not parallel or oblique as in the state of the art. It will be appreciated that this list of benefits is not exhaustive and other benefits will also become apparent in the detailed description of the invention.

Further to the characteristics just discussed in the preceding paragraph, the structure according to a first aspect of the invention may have one or more complementary characteristics from among the following, considered individually or according to any technically possible combinations.

In an embodiment, the conductive element is a microwave resonator or an electrode.

In an embodiment, the opto-mechanical structure comprises at least two conductive elements, a first conductive element located below the movable element and a second conductive element located above the movable element.

In an embodiment, the movable element and the optical resonator are formed using a phoxonic crystal.

In an embodiment, the optical resonator is a gallery mode resonator, with the movable element integrated into the optical resonator. Indeed, as the gallery mode resonator is partially or completely suspended, it also forms a movable element.

In an embodiment, the opto-mechanical resonator comprises a waveguide travelling along the periphery of a central structure, the waveguide being connected to the central structure by anchors, part of the waveguide forming the movable element. It will be noted that, in this structure, the waveguide being looped back on itself, it forms an optical resonator.

In an embodiment, the conductive element comprises a plurality of electrodes, the electrodes being at least partly located facing the movable element.

A second aspect of the invention relates to a method for manufacturing a structure according to a first aspect of the invention comprising, from a semiconductor substrate:
a step of depositing a layer of a first material onto the substrate;
a step of forming a movable element in a piezoelectric material; and
a step of depositing a second material onto the layer of first material and onto the movable element;
a step of forming a conductive element in the layer of second material;
a step of isotropically etching the layer of first material and the layer of second material so as to release the movable element.

In an embodiment, the structure includes a first conductive element and a second conductive element, the method comprising, prior to the step of depositing a layer of a first material onto the substrate, a step of forming a first conductive element at the substrate, the conductive element in the layer of second material forming the second conductive element.

A third aspect of the invention relates to a method for manufacturing a structure according to a first aspect of the invention comprising, from a semiconductor substrate:
a step of depositing a layer of a first material onto the substrate;
a step of forming a conductive element in the layer of first material; and
a step of depositing a layer of a second material onto the layer of first material and onto the conductive element;
a step of forming a movable element in a piezoelectric material;
a step of isotropically etching the layer of the second material so as to release the movable element.

In an embodiment, during the isotropic etching step, the layer of the first material is also etched so as to release the conductive element.

In an embodiment, the optical resonator is made using an element separate from the movable element and the step of forming a movable element also comprises forming an optical resonator.

The invention and its different applications will be better understood upon reading the following description and examining the accompanying figures.

### BRIEF DESCRIPTION OF THE FIGURES

The figures are set forth by way of indicating and in no way limiting purposes of the invention.

FIG. 1A and FIG. 1B show a schematic representation of a structure according to the invention.

FIG. 2A and FIG. 2B schematically show an embodiment in which the opto-mechanical resonator is both a gallery (optical) mode resonator and a breathing (mechanical) mode resonator.

FIG. 3 schematically shows an embodiment in which the opto-mechanical resonator is made by means of a beam inserted into an optical cavity.

FIG. 4 schematically shows an embodiment in which the opto-mechanical resonator is a phoxonic crystal.

FIG. 5 schematically shows an embodiment in which the opto-mechanical resonator is made using a mechanically decoupled mechanical and optical resonator.

FIG. 6A, FIG. 6B, FIG. 7 and FIG. 8 schematically show different geometries that can be assumed by the conductive element(s).

FIG. 9 and FIG. 10A to FIG. 10L schematically show a first manufacturing method.

FIG. and FIG. 12A to FIG. 12H schematically show a second manufacturing method.

### DETAILED DESCRIPTION

Unless otherwise specified, a same element appearing in different figures has a single reference.

Opto-Mechanical Structure

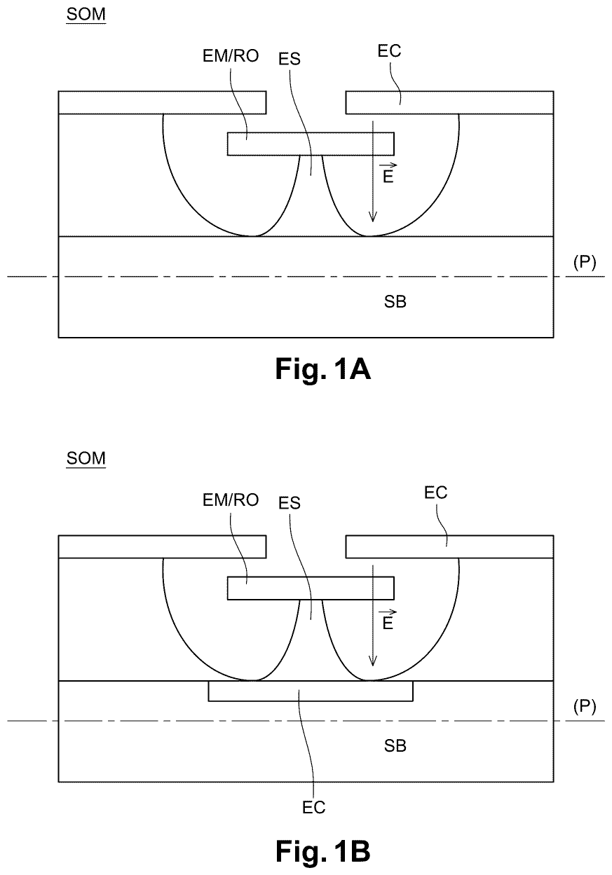

As illustrated in [FIG. 1A] and [FIG. 16], a first aspect of the invention relates to an opto-mechanical structure SOM including a substrate SB extending along a plane P, a support element ES arranged on the substrate SB, at least one conductive element EC adapted to create an electric field oriented perpendicularly to the plane P of the substrate SB.

In this description, by “oriented perpendicularly”, it is meant that the associated angle is between 65 and 115 degrees, and desirably between 85 and 95 degrees. The angle considered here for the electric field is, for example, the angle defined between the direction of the electric field and the plane P of the substrate SB.

The opto-mechanical structure SOM also comprises an opto-mechanical resonator including a mechanically movable element EM, hereinafter referred to as the movable element EM, made of a piezoelectric material and arranged on the support element ES, and an optical resonator RO coupled to the movable element EM. Thus, the optical resonator RO and the movable element EM form an opto-mechanical resonator.

In [FIG. 1A] and [FIG. 1B], the piezoelectric movable element EM is also an optical resonator RO so that it forms on its own an opto-mechanical resonator. In other embodiments illustrated below, the movable element EM and the optical resonator RO may be made of separate elements, possibly made of different materials.

Furthermore, in the structure SOM according to an embodiment of the invention, the piezoelectric material of the movable element EM is chosen so that the electric field \vec{E} created by the conductive element EC or the conductive elements EC, when the latter are subjected to an electric potential, causes a displacement of the movable element EM. It will be noted that the displacement generated by a given electric field \vec{E} is not necessarily collinear with the electric field \vec{E}. In an embodiment illustrated in [FIG. 1A], the structure SOM according to the invention comprises a single conductive element EC, the conductive element EC being located above or below the movable element EM, at a non-zero distance from the movable element EM, the conductive element EC and the movable element EM having a surface facing each other.

In the present description, the expression “one surface facing another” is taken to mean that the two surfaces concerned are at least partly placed facing each other. More particularly, it is possible, for example, to define an overlapping surface which corresponds to the zone of each of the surfaces concerned actually positioned opposite each other. Here, this overlapping surface represents at least 5% of each of the surfaces concerned. In an embodiment, this overlapping surface represents at least 15% of each of the surfaces concerned. In an embodiment, this overlapping surface represents at least 30% of each of the surfaces concerned.

In other words, here, an overlapping surface is defined between the conductive element EC and the movable element EM so that these two elements have a(n) (at least partly) surface facing each other. This overlapping surface corresponds to the part of the surface of the conductive element EC or to the part of the surface of the movable element EM which face each other.

In this embodiment, the conductive element EC forms a microwave resonator configured to generate the electric field \vec{E}.

In one alternative embodiment illustrated in [FIG. 1B], the structure according to the invention comprises two conductive elements EC: a first conductive element EC located above the movable element EM and a second conductive element EC located below the movable element EM, at least one of these two conductive elements EC, for example both conductive elements EC, having a part facing a part of the movable element EM. It will be appreciated that it is also possible to envisage such a structure with three or more conductive elements EC.

In the structure SOM according to the invention, when the movable element EM is located in a cavity, the latter can be filled with a gas, a liquid or left under vacuum (that is at a pressure of less than one mbar). In addition, in the structure SOM according to the invention, the conductive element(s) EC which are responsible for actuating the movable element EM are not in contact with the movable element EM and therefore do not disturb its movement. Furthermore, when the coupling between the movable element EM and the optical resonator RO takes place by means of evanescent waves, the risk of the waves being partially or totally absorbed by the conductive element(s) EC is strongly reduced.

In addition, the structure according to the SOM invention, by being compatible with electronic micro-fabrication methods, makes it possible to control distance between the movable element EM and the conductive element(s) EC and thus generate strong electric fields at the movable element EM, in a reproducible manner.

Operating Principle

An opto-mechanical resonator generally comprises a movable element EM likely to move (for example, to vibrate at a given frequency) of its own and a means for optically reading this movement, generally an optical resonator RO (or optical cavity).

In a first operating example, the structure comprises two conductive elements EC located above and below the movable element EM, at least one of these two conductive elements having a part facing a part of the movable element EM, the two conductive elements EC are brought to different electrical polarisations, inducing the creation of a homogeneous electric field \vec{E} between the conductive elements EC. Returning to the diagram of [FIG. 16], the movable element EM has electric field lines \vec{E} substantially (+/−20°, or even)+/−10° vertical relative to the surface of the substrate SB passing therethrough. It is then possible to achieve deformations in several spatial directions by piezoelectric coupling.

In a second operating example, the structure comprises only one conductive element EC forming a microwave resonator. The principle is similar except that the electric field \vec{E} is induced by an evanescent wave and therefore the decrease in the intensity of the electric field \vec{E} is spatially exponential, and not uniform as in the previous case. Hence, in this embodiment, particular attention should therefore be paid to the distance separating the conductive element EC from the movable element EM.

Examples of Opto-Mechanical Resonators According to the Invention

Gallery Mode Resonator

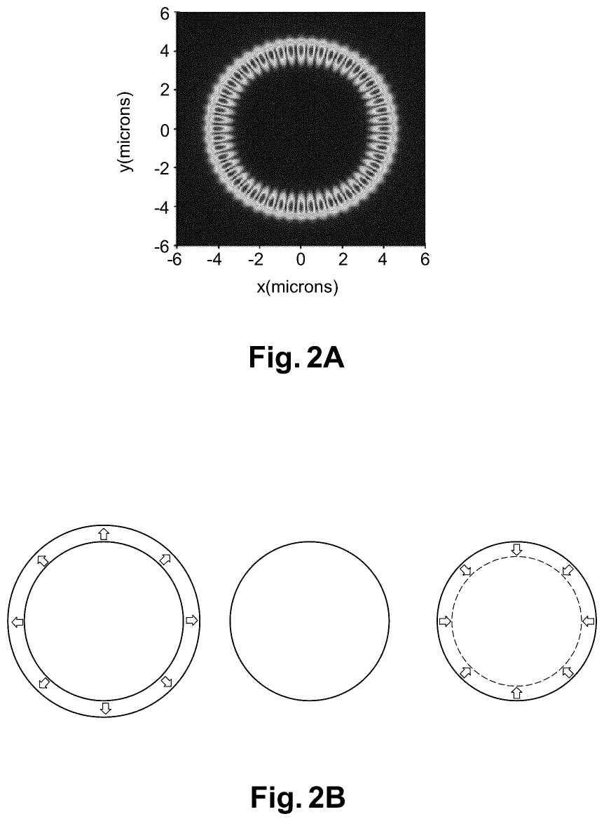

In an embodiment illustrated in [FIG. 2A] and [FIG. 2B], the movable element EM and the optical resonator RO are made by means of a gallery mode resonator. Strictly speaking, gallery mode resonators are optical resonators with a geometry that allows the optical mode to loop back on itself, for example a geometry with cylindrical or spherical symmetry. They can also have mechanical modes to form opto-mechanical resonators. For example, such resonators can take the form of a ring, a wheel, a disc or a sphere. In an embodiment, light propagating in this type of cavity is located at the ends of the structure as illustrated in [FIG. 2A] which shows the electric field intensity in the plane of the movable element EM in the case of a circular movable element EM. At each revolution in the resonator, this interferes with itself, giving rise to constructive interference. The optical resonator (or optical cavity) thus obtained filters out all wavelengths except those that meet the constructive interference conditions.

Several vibration modes can be exhibited. In an embodiment, the movable element EM vibrates according to a breathing mode illustrated in [FIG. 2B]. In this way, wavelengths filtered by the optical resonator RO are a function of the vibrations of the movable element EM so as to form an opto-mechanical resonator. These resonators have the benefit of providing very high coupling, that is for a given mechanical displacement, the resonance wavelength shift is high. This is particularly true for a mechanical displacement associated with the aforementioned breathing mode in the simple case of a disc, that is isotropic deformation in the plane of the movable element EM.

In an embodiment, the movable element EM is made of aluminium nitride deposited onto silicon oxide. The deposition conditions imply anisotropy of the material along the axis perpendicular to the plane (P) of the substrate SB and isotropy in the plane parallel to the plane (P) of the substrate. To actuate the first breathing mode described above, it is then necessary for the material to couple to an electric field whose vertical component with respect to the plane of the disc, that is the plane (P) of the substrate, is non-zero.

Beam Inserted into an Optical Cavity

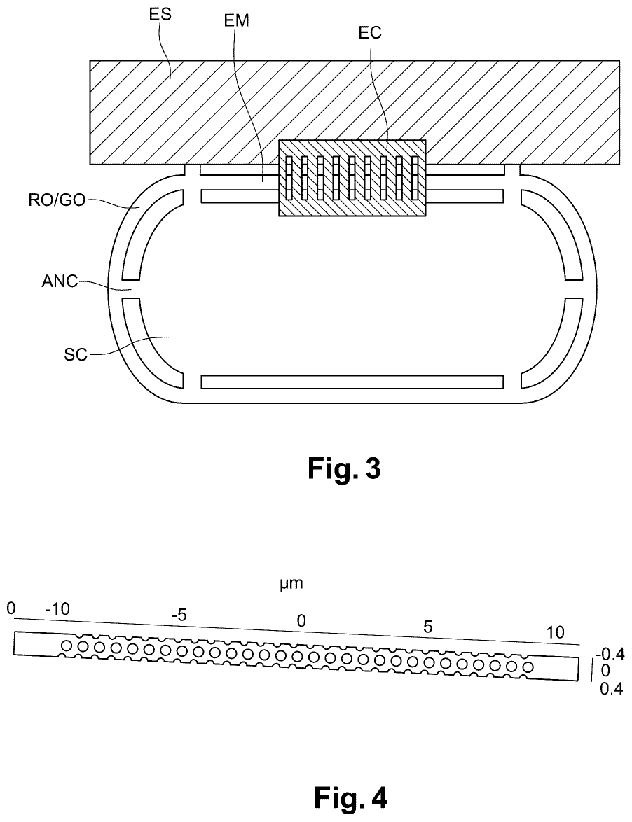

In a second exemplary embodiment illustrated in [FIG. 3], the opto-mechanical resonator comprises a waveguide GO travelling along the periphery of a central structure SC to which it is connected through anchors AC, the waveguide GO forming an optical resonator RO. In addition, the whole is manufactured from a piezoelectric material M3. The anchors are disposed on the support element ES. Furthermore, the waveguide GO comprises at least one movable part (such as at least two parts) acting as a vibrating beam and forming a movable element EM of the structure SOM according to an embodiment of the invention. In other words, the movable element EM is a constituent part of the waveguide GO in which the optical wave propagates. Thus, deformation of this movable element EM leads to deformation and/or disturbance of the optical properties of the waveguide GO, thus achieving opto-mechanical coupling. In an embodiment, the movable element EM is rectilinear. In an embodiment, the width of the waveguide is between 200 nm and 1000 nm. In an embodiment, the length of the waveguide is between 5 μm and 50 μm. In an embodiment, the radius of curvature of the curved portion of the waveguide is between 5 μm and 50 μm. In an embodiment, the width of the conductive element EC (measured along the main axis of the waveguide GO at the conductive element EC) is between 100 nm and the length separating two antinodes of the mechanical wave considered of the movable element EM.

The above structure generally takes the form of a racetrack. This is for example the approach implemented by Westwood-Bachman et al. in “Integrated silicon photonics transduction of even nanomechanical modes in a doubly clamped beam”, which actuates a doubly clamped beam by virtue of an optical force (there is therefore no piezoelectric actuation as in the present invention). Furthermore, the structure according to an embodiment of the invention includes two conductive elements EC: a first conductive element located above a portion of the movable element EM and a second conductive element EC located below a portion of the movable element EM so as to be able to actuate the movable element EM. Such a configuration in which the displacement of the movable element EM is vertical with respect to the plane (P) of the substrate (therefore substantially parallel to the electric field generated by the conductive element EC) generally offers better energy exchange (electro-mechanical coupling) than the configuration in which the displacement is radial (for example with resonator in gallery mode set forth previously).

In an embodiment, at least one of the conductive elements EC comprises a plurality of electrodes, the electrodes being at least partly located facing the movable element EM. It is thus possible to selectively actuate a harmonic of the movable element EM by positioning the electrodes of the conductive element EC above the antinodes of the standing wave of the movable element EM.

In another alternative embodiment, the conductive elements EC located above and below the movable element EM are solid electrodes. In addition, anchors are disposed at the zero-displacement zones of the movable element EM.

Phoxonic Crystals

As a reminder, phoxonic crystals are resonators that behave as both photonic crystals (optical resonators), that is structures capable of confining an optical wave within a restricted volume, and as phononic crystals (mechanical resonators), their equivalent for mechanical waves. The principle behind these crystals is to locate a strong optical field and a mechanical displacement field in the same space. In general, these structures include a pattern repeated periodically in space, as well as an artificial defect whose purpose is to trap the optical and mechanical waves. These resonators are well known in the field of opto-mechanics and are therefore not detailed here. For more details, the reader may especially refer to the article Ghorbel et al. 2019, “Optomechanical gigahertz oscillator made of a two photon absorption free piezoelectric III/V semiconductor”.

In a third exemplary embodiment, the optomechanical resonator is a phoxonic crystal, for example a beam configured to form a phoxonic crystal as illustrated in [FIG. 4]. In the exemplary embodiment illustrated in [FIG. 4], the opto-mechanical resonator is made using a “bichromatic mesh”. More particularly, in this embodiment, the opto-mechanical resonator comprises a beam forming the movable element EM and in which openings are made in the central part of the beam and at its periphery so as to form an optical resonator RO. In addition, the spacing between openings made in the central part of the beam and those made at its periphery is different so as to obtain a confinement effect for the mechanical wave and the optical wave. In an embodiment, the beam has a length of between 5 μm and 50 μm, the internal openings made in the beam at its central part to form the phoxonic crystal have a radius of between 100 nm and 500 nm, and the external openings made in the beam at its periphery to form the phoxonic crystal have a radius of between 50 nm and 200 nm.

The structure SOM according to the invention has the benefit of enabling this type of resonator to be actuated piezoelectrically by positioning the conductive element EC located above the movable element EM and/or the conductive element EC located below the movable element EM at the mechanical displacement zone thereof (that is of the phoxonic crystal), for example the centre of the beam. According to the piezoelectric tensor of the material used, the vertical electric field can then induce radial deformation of the resonator.

Mechanically Decoupled Optical and Mechanical Resonator

In the preceding examples, there is a mechanical coupling between the optical resonator RO and the movable element EM. However, it is possible to make an opto-mechanical resonator in which coupling between the movable element EM (piezoelectrically actuated) and the optical resonator RO is via an evanescent wave, the wave originating from the optical resonator RO and interacting with the movable element EM (via the electric field associated with the evanescent wave). When the movable element EM and the optical resonator RO are one and a single structure, the conductive element(s) EC in charge of actuating the movable element EM may disturb the optical field, which is fairly close thereto, and degrade reading.

An aspect of the invention, by allowing indirect coupling (coupling takes place via the movable element EM) of the conductive elements EC responsible for actuating the optical resonator RO, makes it possible to prevent drawbacks set out previously. In this exemplary embodiment, the movable element EM is necessarily made of a piezoelectric material in order to enable the latter to be actuated, but the optical resonator RO may be made of a different material. For example, the layer in which the opto-mechanical resonator is made may include two different sub-layers: a piezoelectric sub-layer (for example AlN) in which the movable element EM is made and a structural sub-layer (for example made of Si) which has good mechanical and optical properties and in which the optical resonator RO is made.

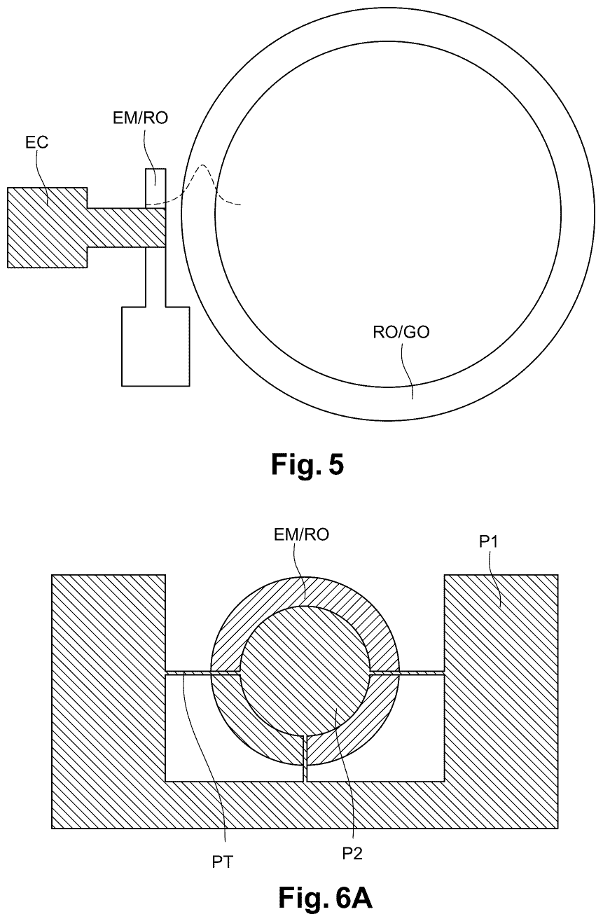

One exemplary embodiment is illustrated in [FIG. 5], in which the opto-mechanical resonator comprises, in addition to the movable element EM (acting as a mechanical resonator), a ring waveguide GO forming an optical resonator RO, the distance separating the movable element EM from the waveguide GO being chosen so as to allow coupling between the optical resonator RO and the movable element EM by means of an evanescent wave from the waveguide GO. A similar system, but without piezoelectric actuation, is for example described in document Leoncino et al, “Optomechanical nanoresonator readout with optical downmixing”, 2016 IEEE International Frequency Control Symposium (IFCS). A piezoelectric actuation is especially made possible by the fact that, in the structure SOM according to the invention, the conductive element(s) EC for actuation are not disposed in contact with the movable element EM, which avoids absorption of the evanescent wave.

Geometry of the Conductive Element or Elements

The conductive element(s) EC located above the movable element EM may assume different geometries depending on the restrictions and applications.

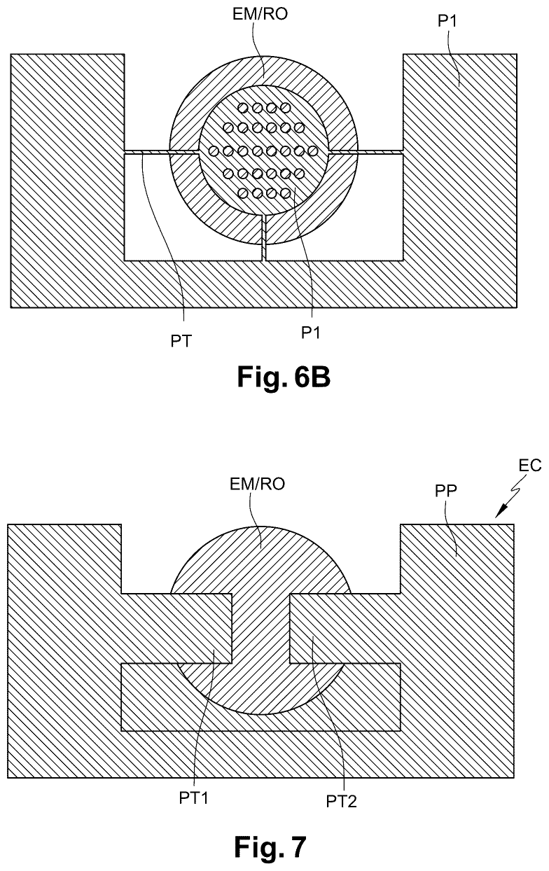

In a first embodiment illustrated in [FIG. 6A], the movable element EM has the shape of a disc in a plane parallel to the plane P of the substrate SB. In addition, the conductive element EC located above the movable element EM comprises a first part P1 and a second part P2, the second part P2 being disc-shaped, the first part P1 at least partially surrounding the second part P2 and not facing the movable element EM, the second part P2 being connected to the first part P1 through one or more beams PT and being disposed facing the movable element EM. In an embodiment, the centre of the second part P2 and the centre of the movable element EM lie on a same axis, the axis being perpendicular to the movable element EM (that is perpendicular to the plane P of the substrate SB). In an embodiment, the surface area of the second part P2 is smaller than that of the movable element EM so that the periphery of the movable element EM does not face the second part P2 (or the first part P1). In an embodiment, as illustrated in [FIG. 6B], through openings are made in the second part P2.

In a second embodiment illustrated in [FIG. 7], the movable element EM is disc-shaped, the disc being disposed in a plane parallel to the plane P of the substrate SB. In addition, the conductive element EC located above the movable element EM comprises a main part PP surrounding the mechanical element EM (without facing it) and serving as an anchor, and at least one electrode, for example two electrodes, connected to the main part PP, part of the surface of the electrodes PT1, PT2 facing the movable element EM. In an embodiment, through openings are made in the electrode(s) PT1,PT2, at least in the part facing the movable element EM.

In a third embodiment illustrated in [FIG. 8], the movable element EM is disc-shaped, the disc being disposed in a plane parallel to the plane P of the substrate SB. In addition, the conductive element EC located above the movable element EM is configured so as to face at least part of the periphery of the movable element EM. Stated differently, the conductive element EC located above the movable element EM does not face the central part of the movable element EM and, for example, faces only part of the periphery of the movable element EM. In an embodiment, through openings are made in the conductive element EC located above the movable element EM, at least in the part facing the movable element EM.

Geometries described above are particularly adapted to the gallery mode resonator, in particular when the latter takes the form of a disc as previously described.

It will be noted that all these geometries relate to the conductive element EC situated above the movable element EM (that is the movable element EM is in a plane situated between the conductive element EC considered and the substrate SB) and that a conductive element EC (not represented in the figures) is also disposed below the movable element EM (that is the conductive element EC considered is in a plane situated between the movable element EM and the substrate SB or directly in the substrate SB). In an embodiment, the conductive element EC below is configured to create, together with the conductive element EC situated above, an electric field in the most piezoelectrically coupled direction so as to promote electromechanical coupling of the movable element EM. For example, if the piezoelectric material is AlN, the electric field will be out-of-plane with respect to the substrate. In an embodiment, the conductive element EC below has the same circular geometry as the movable element EM (disc-shaped).

Possible Applications

A structure SOM according to the invention can be used in many applications, only some of which will be detailed below.

A structure SOM according to an embodiment of the invention can be used in a resonant sensor. For the record, the natural frequency of a mechanical resonator depends on several measurable parameters (mass, acceleration, pressure, etc.). Hence, any variation in one of these parameters causes a shift in the oscillator frequency. Quantifying this shift thus enables the measured quantity to be deduced. Resonant sensors should have high-performance actuation systems capable of generating the highest possible amplitude of mechanical displacement, coupled with an also high mechanical frequency.

A structure SOM according to an embodiment of the invention can also be used in a time base generator. For the record, the operation of time bases is opposite to that of resonant sensors: the aim is to keep the frequency as stable as possible. These time bases serve especially in digital electronics and telecommunications to generate signals and synchronise different components. In these systems, actuation is essential in order to use the full usable dynamic range, that is to use a signal with the widest possible amplitude.

A structure SOM according to an embodiment of the invention can also be used in a frequency converter. As a reminder, frequency converters are especially used within the scope of quantum information technologies. They serve to convert photons in the microwave range into photons in the optical range (visible and near infrared) and vice versa. Conversion is achieved by coupling a microwave resonator and an opto-mechanical resonator. Microwave photons entering the system resonate at their natural frequency in a superconducting cavity and actuate the mechanical resonator. An optical transduction system then recovers an optical signal modulated at the resonance frequency of the microwave photons.

A structure SOM according to an embodiment of the invention can also be used in a static sensor. In such a sensor, the mechanical element is not a resonator, but is free to deform and disturb the optical field. This case describes so-called static sensors (acceleration, pressure, etc.) with opto-mechanical reading. In several cases, actuation of the movable element EM (for example piezoelectric) should be used to compensate for drift or static offset.

Manufacturing Methods

First Method

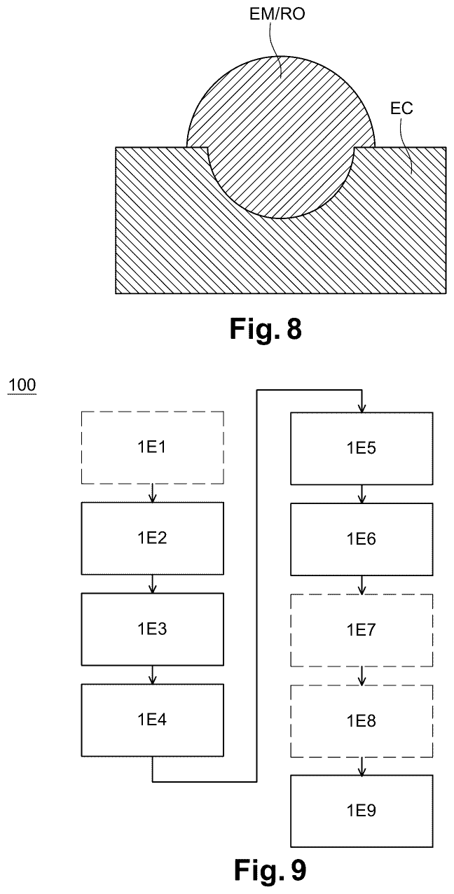

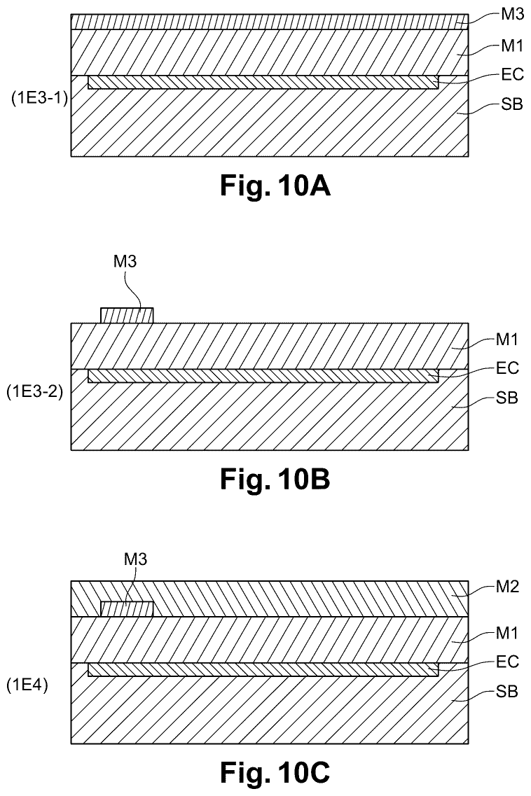

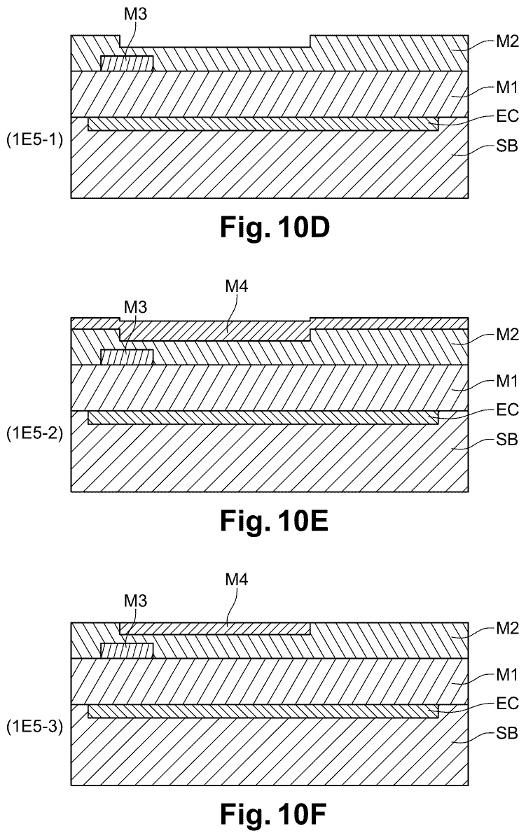

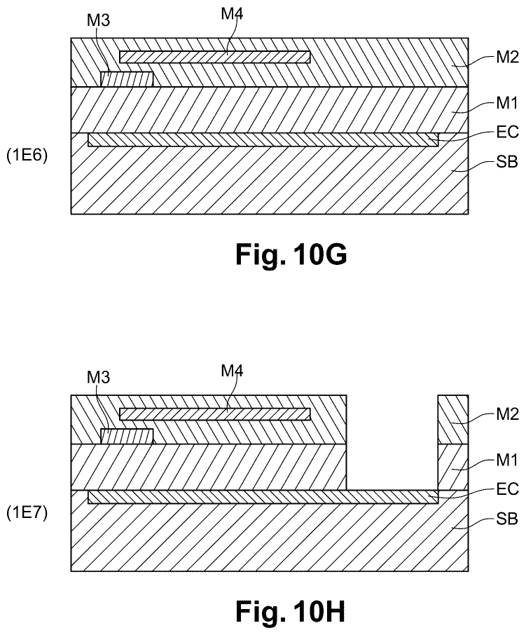

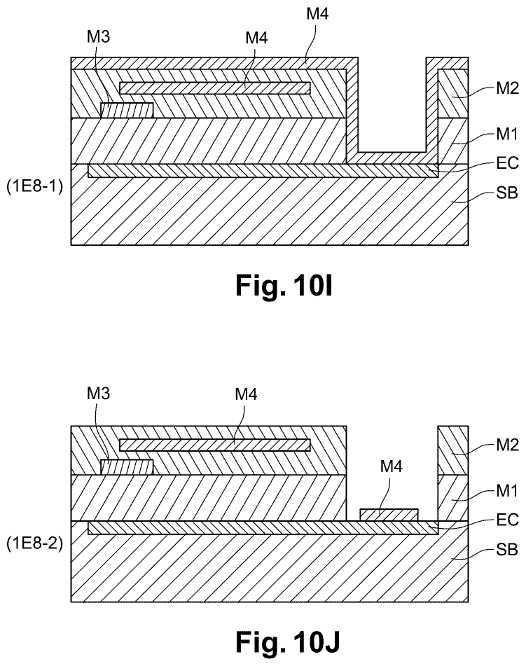

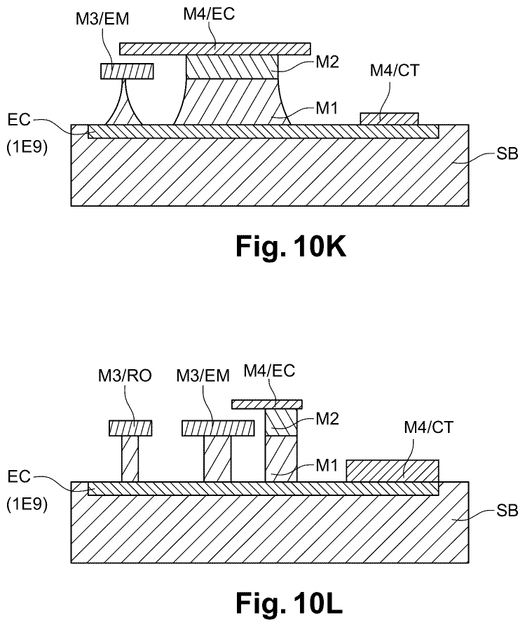

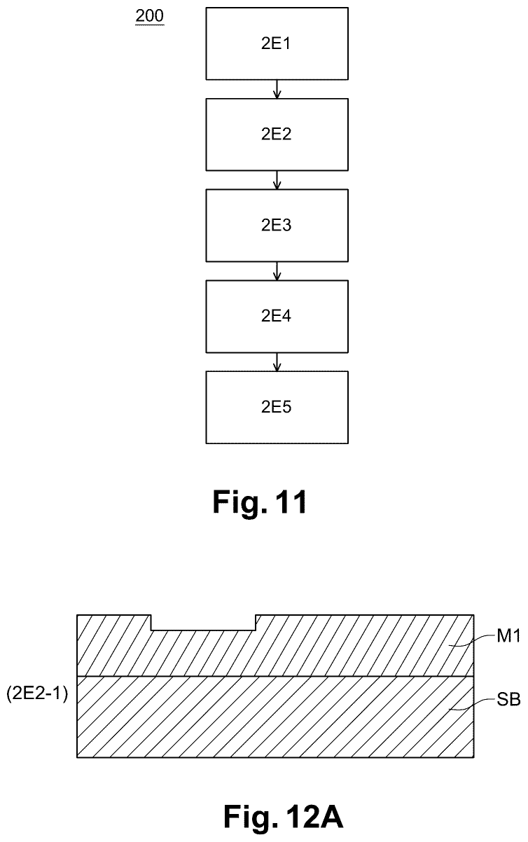

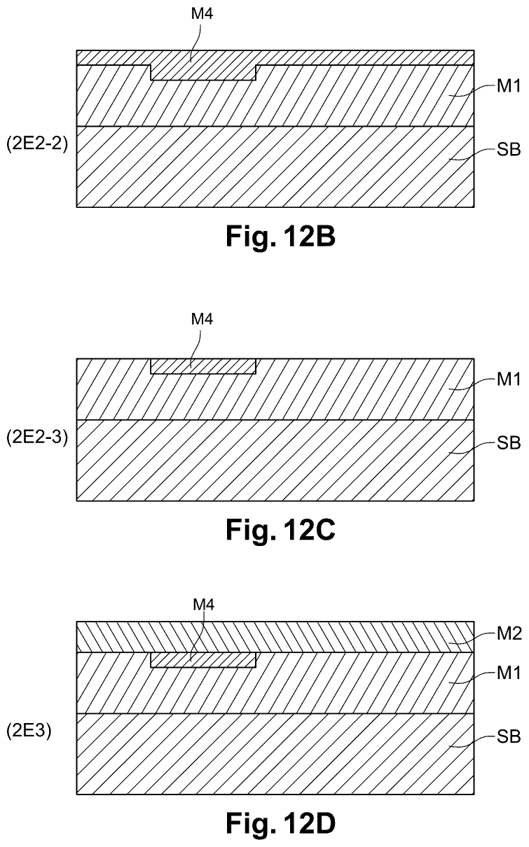

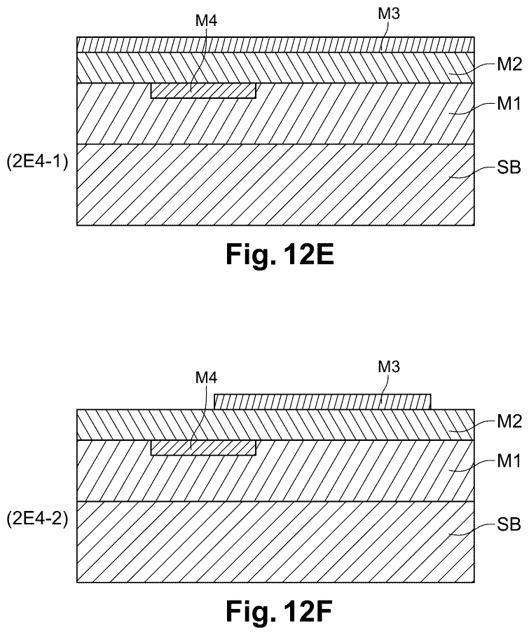

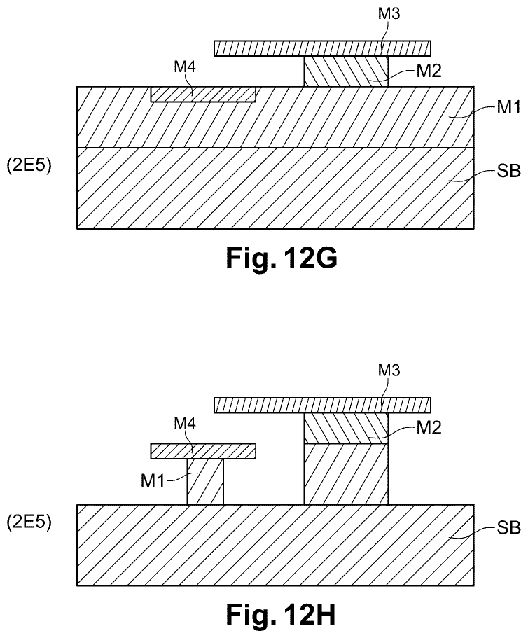

A second aspect of the invention illustrated in [FIG. 9] and [FIG. 10A] to [FIG. 10L] relates to a first method 100 for manufacturing a structure SOM according to the invention, the method 100 in question being carried out from a semiconductor substrate SB, such as a silicon substrate SB.

In an embodiment, the method 100 comprises a step 1E1 of making a first conductive element EC at the substrate SB. In an exemplary embodiment, this conductive element EC is obtained by doping at least part of the substrate SB so as to define the conductive element EC in the substrate SB. Alternatively, this conductive element EC is obtained by depositing a layer of metal on the surface of the substrate so as to form the conductive element.

The method comprises a step 1E2 of (physically or chemically) depositing a layer of a first material M1 onto the substrate SB. In an embodiment, the layer deposited in this way has a thickness of between 1 μm and 2 μm, for example equal to 1.5 μm. This layer of the first material M1 is to provide structural support for the movable element and therefore for the opto-mechanical resonator. In an embodiment, the first material is chosen so that it can be etched isotropically in order to be able (in the following steps) to release the movable element so that the latter can vibrate freely. In one exemplary embodiment, the first material M1 is silicon oxide (SiO₂) or an alloy of aluminium, gallium and arsenic (AlGaAs), these materials being able, for example, to be etched using hydrofluoric acid (HF).

The method then comprises a step 1E3 of forming a movable element EM, and optionally an optical resonator RO, in a piezoelectric material M3. In an embodiment, the layer of piezoelectric material deposited during this step 1E3 has a thickness of between 0.3 μm and 0.4 μm, for example equal to 0.35 μm. In an embodiment, the piezoelectric material M3 is a dielectric so as to allow passage of an electromagnetic wave. The piezoelectric material M3 is also chosen to resist etching of the first material M1 or the second material M2 (introduced later). In an exemplary embodiment, the piezoelectric material M3 is aluminium nitride (AlN), lithium niobate (LiNbO3 or LNO for lithium-niobium-oxide), or lithium-titanate (or LTO for lithium-titanium-oxide). As illustrated in [FIG. 10B], when step 1E1 of making a first conductive element EC at the substrate is implemented, then the movable element EM formed in this step 1E3 has at least one part (in the example of [FIG. 10B] the entirety) facing the first conductive element EC.

In an embodiment illustrated in [FIG. 10A] and [FIG. 10B], this step 1E3 of forming a movable element EM in a piezoelectric material M3 firstly comprises a sub-step 1E3-1 of depositing (see [FIG. 10A]), onto the layer of the first material M1, a layer of the piezoelectric material M3 (deposition is particularly adapted when the material M1 is AlN). It also comprises a lithography sub-step so as to define patterns of the movable element EM and, optionally, of the optical resonator RO. Finally, it comprises a sub-step 1E3-2 of etching the layer of piezoelectric material M3 (see [FIG. 10B]) so as to transfer the patterns defined during the lithography sub-step into the layer. In an alternative embodiment, the layer of first material M1 is not deposited but bonded using a Smartcut™ type technique. This alternative is in particular adapted when the material M1 is LNO or LTO.

As illustrated in [FIG. 100], the method 100 then comprises a step 1E4 of depositing a second material M2 onto the layer of first material M1 and onto the movable element EM. In an embodiment, the second material M2 is identical to the first material M1. In an embodiment, the thickness of the layer of second material M2 deposited during this step 1E4 is between 0.5 μm and 5 μm, for example equal to 1.05 μm.

The method 100 then comprises a step 1E5 of forming a second conductive element EC (for example an electrode or a microwave resonator) in a conductive material M4 (this material may be superconductive), in the layer of second material M2. In an embodiment, the thickness of the second conductive element EC is between 0.4 μm and 1 μm, for example equal to 0.5 μm. In an embodiment, the distance separating the conductive element EC from the movable element EM and, when it is distinct from the movable element EM, the optical resonator RO, is between 400 nm and 900 nm, for example equal to 700 nm.

In an embodiment illustrated in [FIG. 10D] to [FIG. 10F], step 1E5 of forming a second conductive element EC in the layer of second material M2 is carried out using a Damascene method well known to the skilled person. More particularly, this step 1E5 first comprises a lithography sub-step so as to define patterns of the conductive element EC. This step 1E5 then comprises a sub-step 1E5-1 of partially etching the layer of second material M2 according to the patterns defined during the lithography step ([FIG. 10D]), the thickness remaining after etching being greater than the thickness of the movable element EM. It then comprises a sub-step 1E5-2 of depositing a layer of a conductive material M4 onto the layer of a second etched material M2 ([FIG. 10E]). Finally, it comprises a chemical mechanical polishing sub-step 1E5-3 so as to retain the layer of conductive material M4 only in the etched patterns ([FIG. 10F]). The use of a Damascene method makes it possible especially to achieve higher integration densities. However, if the size of the patterns is not critical, it is possible to simply carry out this step in three stages: deposition of the material, lithography and etching, as for the piezoelectric material M1.

As illustrated in [FIG. 10G], the method 100 then comprises a step 1E6 of depositing a layer of the second material M2 onto the layer of second material M2 already present and onto the second conductive element EC. The purpose of this new layer is to protect the previous layers and in particular the conductive element EC (especially during the etching step).

In an embodiment, as illustrated in [FIG. 10H], when step 1E1 of making a first conductive element EC at the substrate SB is implemented, the method 100 comprises a step 1E7 of forming an opening in the layer of first material M1 and the layer of second material M2 so as to expose the first conductive element EC. This opening can, for example, be made using a lithography sub-step for defining the pattern associated with the opening, followed by a sub-step of anisotropically etching the layer of first material M1 and the layer of second material M2 according to the pattern defined during lithography.

In this embodiment, the method 100 also comprises a step 1E8 of forming an electrical contact CT on the first conductive element EC. As illustrated in [FIG. 10I] and [FIG. 10J], this step 1E8 can be implemented using a first sub-step 1E8-1 of depositing a conductive material, a lithography sub-step so as to define the pattern associated with the electrical contact CT and a sub-step 1E8-2 of etching the layer of conductive material according to the pattern defined during lithography.

As illustrated in [FIG. 10K], the method 100 comprises a step 1E9 of isotropically etching the layer of first material M1 and the layer of second material M2 so as to release the movable element EM. The final structure of the method 100 according to the invention when the optical resonator RO is made by an element distinct from the movable element EM is illustrated in [FIG. 10L].

Second Method

A third aspect of the invention illustrated in [FIG. 11] and in [FIG. 12A] to [FIG. 12H] relates to a second method 200 for manufacturing a structure SOM according to the invention, the method in question being carried out from a semiconductor substrate SB, such as a silicon substrate SB.

The method comprises a step 2E1 of depositing a layer of a first material M1 onto the substrate SB. In an embodiment, the layer deposited in this way has a thickness of between 1 μm and 2 μm, for example equal to 1.5 μm. This layer of the first material M1 is to provide structural support for the conductive element EC. In an embodiment, the first material M1 is chosen so that it can be etched isotropically in order to be able (in the following steps) to release the conductive element EC. In one exemplary embodiment, the first material M1 is silicon oxide (SiO2) or an alloy of aluminium, gallium and arsenic (AlGaAs), these materials being able, for example, to be etched using hydrofluoric acid (HF).

The method 200 then comprises a step 2E2 of forming a conductive element EC (for example an electrode or a microwave resonator) in the layer of first material M1. In an embodiment, the thickness of the conductive element EC is between 0.4 μm and 1 μm, for example equal to 0.5 μm.

In an embodiment illustrated in [FIG. 12A] to [FIG. 12C], the step 2E2 of forming a conductive element EC in the layer of first material M1 is carried out using a Damascene method well known to the person skilled in the art. More particularly, this step 2E2 first comprises a lithography sub-step so as to define patterns of the electrode. It then comprises a sub-step 2E2-1 of partially etching the layer of first material M1 according to the patterns defined during the lithography step ([FIG. 12A]). It then comprises a sub-step 2E2-2 of depositing a layer of a conductive material M4 (this material may be superconductive) onto the etched layer of a first material M1 ([FIG. 12B]). Finally, it comprises a chemical-mechanical polishing sub-step 2E2-3 so as to retain the layer of conductive material M4 only in the etched patterns ([FIG. 12C]). As already mentioned, the use of a Damascene method makes it possible especially to achieve higher integration densities.

As illustrated in [FIG. 12D], the method 200 then comprises a step 2E3 of depositing a layer of a second material M2 onto the layer of first material M1 and onto the conductive element EC. In an embodiment, the second material M2 is identical to the first material M1. In an embodiment, the thickness of the layer of second material M2 deposited during this step 2E3 is between 0.5 μm and 5 μm, for example equal to 1.05 μm.

The method 200 then comprises a step 2E4 of forming a movable element EM and, optionally, an optical resonator RO, in a piezoelectric material M3. In an embodiment illustrated in [FIG. 12E] and [FIG. 12F], this step 2E4 first comprises a sub-step 2E4-1 of depositing, onto the layer of the second material M2, a piezoelectric material M3 ([FIG. 12E]). It also comprises a lithography sub-step so as to define patterns of the movable element EM and, optionally, of the optical resonator RO. Finally, it comprises a sub-step 2E4-2 of etching the layer of piezoelectric material M3 so as to transfer the patterns of the movable element EM and, optionally, of the optical resonator RO, defined during the lithography sub-step ([FIG. 12F]) into the layer.

As illustrated in [FIG. 12G], the method 200 finally comprises a step 2E5 of isotropically etching the layer of the second material M2 so as to release the movable element EM. In an embodiment illustrated in [FIG. 12H], during this step 2E5, the layer of the first material M1 is also etched so as also to release the conductive element EC.

The articles “a” and “an” may be employed in connection with various elements and components, processes or structures described herein. This is merely for convenience and to give a general sense of the processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations.

1. An opto-mechanical structure including:
a substrate extending along a plane;
a support element arranged on the substrate;
at least one conductive element adapted to create an electric field oriented perpendicularly to the plane of the substrate;
an opto-mechanical resonator including:
a mechanically movable element made of a piezoelectric material and arranged on the support element, the piezoelectric material being chosen so that the electric field created by the conductive element when the same is subjected to an electric potential causes a displacement of said movable element;
an optical resonator coupled to the movable element;
said at least one conductive element being located above or below said movable element, at a non-zero distance from said movable element, said conductive element and said movable element having at least one surface facing each other.

2. The opto-mechanical structure according to claim 1, wherein the conductive element is a microwave resonator or an electrode.

3. The opto-mechanical structure according to claim 1, comprising at least two conductive elements, a first conductive element located below the movable element and a second conductive element located above the movable element.

4. The opto-mechanical structure according to claim 1, wherein the movable element and the optical resonator are formed by a phoxonic crystal.

5. The opto-mechanical structure according to claim 1, wherein the optical resonator is a gallery mode resonator, the movable element being integrated into the optical resonator.

6. The opto-mechanical structure according to claim 1, wherein the opto-mechanical resonator comprises a waveguide travelling along the periphery of a central structure, the waveguide being connected to the central structure through anchors, part of the waveguide forming the movable element.

7. The opto-mechanical structure according to claim 6, wherein the conductive element comprises a plurality of electrodes, said plurality of electrodes being at least partly situated facing the movable element.

8. A method for manufacturing a structure according to claim 1, comprising, from a semiconductor substrate:
so a step of depositing a layer of a first material onto the substrate;
a step of forming a movable element in a piezoelectric material;
a step of depositing a second material onto the layer of first material and onto the movable element;
a step of forming a conductive element in the layer of second material, and
a step of isotropically etching the layer of first material and the layer of second material so as to release the movable element.

9. The method according to claim 8, wherein the structure includes a first conductive element and a second conductive element, the method including, before the step of depositing a layer of a first material onto the substrate, a step of making a first conductive element at the substrate, the conductive element in the layer of second material forming the second conductive element.

10. The method according to claim 8, wherein the optical resonator is made using an element distinct from the movable element and the step of forming a movable element also comprises forming an optical resonator.

11. A method for manufacturing a structure according to claim 1, comprising, from a semiconductor substrate:
a step of depositing a layer of a first material onto the substrate;
a step of forming a conductive element in the layer of first material;
a step of depositing a layer of a second material onto the layer of first material and onto the conductive element;
a step of forming a movable element in a piezoelectric material, and
a step of isotropically etching the layer of the second material so as to release the movable element.

12. The manufacturing method according to claim 11, wherein, during the isotropic etching step, the layer of the first material is also etched so as to release the conductive element.

13. The method according to claim 11, wherein the optical resonator is made using an element distinct from the movable element and the step of forming a movable element also comprises forming an optical resonator.
